(19) United States
(12) Patent Application Publication
(10) Pub. No.: US 2023/0393477 A1
(43) Pub. Date: Dec. 7, 2023

(54) HIGH-TEMPERATURE METHODS OF FORMING PHOTORESIST UNDERLAYER AND SYSTEMS FOR FORMING SAME

(71) Applicant: ASM IP Holding B.V., Almere (NL)

(72) Inventor: Fanyong Ran, Tokyo (JP)

(21) Appl. No.: 18/203,873

(22) Filed: May 31, 2023

Related U.S. Application Data
(60) Provisional application No. 63/348,689, filed on Jun. 3, 2022.

(51) Int. Cl. G03F 7/11; H01L 21/027; C23C 16/455; C23C 16/40; C23C 16/32

(52) U.S. Cl. CPC G03F 7/11; H01L 21/0273; C23C 16/45536; C23C 16/401; C23C 16/405; C23C 16/407; C23C 16/325

(57) ABSTRACT

Methods of forming structures including photoresist underlayers and adhesion layers are disclosed. Exemplary methods include forming an adhesion layer using plasma-enhanced cyclical deposition processes.

### CROSS-REFERENCE TO RELATED APPLICATIONS

This application claims priority to U.S. Provisional Patent Application Ser. No. 63/348,689 filed Jun. 3, 2022 and titled HIGH-TEMPERATURE METHODS OF FORMING PHOTORESIST UNDERLAYER AND SYSTEMS FOR FORMING SAME, the disclosure of which is hereby incorporated by reference in its entirety.

### FIELD OF INVENTION

The present disclosure generally relates to methods and structures suitable for use with photoresist patterning techniques. More particularly, the disclosure relates to structures including or formed using a photoresist underlayer and to methods of forming such structures.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it becomes increasingly desirable to form features with smaller dimensions.

Photoresist is often used to pattern a surface of a substrate prior to etching. A pattern can be formed in the photoresist by applying a layer of photoresist to a surface of the substrate, masking the surface of the photoresist, exposing the unmasked portions of the photoresist to radiation, such as ultraviolet light, and removing a portion (e.g., the unmasked or masked portion) of the photoresist, while leaving a portion of the photoresist on the substrate surface.

Recently, techniques have been developed to use extreme ultraviolet (EUV) wavelengths to develop patterns having relatively small pattern features (e.g., 10 nm or less). EUV lithography techniques may include the use of an underlayer to obtain desired line width roughness and/or line edge roughness in patterned features.

Structures that include certain underlayers, such as those including titanium oxide, may include an adhesion or glue layer that is deposited at relatively low temperatures. The relatively low temperature can negatively impact throughput because, for example, components within a reaction chamber may need to be heated above the deposition temperature to perform a cleaning step. Many precursors used to deposit the adhesion layer will not form deposited material at temperatures at or near desired cleaning temperatures. Therefore, improved methods of forming a structure comprising an adhesion layer, particularly those methods that operate at relatively high deposition temperatures, are desired.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to methods and systems for forming structures that include photoresist underlayers and adhesion layers. While the ways in which various embodiments of the present disclosure address drawbacks of prior methods and systems are discussed in more detail below, in general, various embodiments of the disclosure provide methods that can form adhesion layers at relatively high temperatures. Consequently, methods described herein can exhibit a relatively high throughput and relatively low cost of ownership.

In accordance with exemplary embodiments of the disclosure, a method of forming a structure comprising a photoresist underlayer includes providing a substrate within a reaction chamber, forming a photoresist underlayer overlying a surface of the substrate using a first plasma process, and forming an adhesion layer using a second plasma process, wherein the second plasma process is performed at a temperature greater than 75° C., 85° C., or 100° C., or at a temperature of at least 100° C. and no more than 180° C. or at a temperature of at least 180° C. and no more than 300° C. In accordance with examples of these embodiments, the step of forming the adhesion layer includes providing a silicon precursor to the reaction chamber, providing oxygen-free gas into the reaction chamber, and forming activated species that react with the silicon precursor or a derivative thereof to form the adhesion layer. The photoresist underlayer can include, for example, one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. In accordance with further examples of these embodiments, the silicon precursor includes one or more of: (i) a molecule comprising a backbone comprising: Si—(CH₂)ₙ—Si, where n can range from about 1 to about 10; or (ii) a molecule comprising a carbon-carbon double bond. In some cases, the molecule includes two or more silicon-oxygen bonds. In some cases, the molecule includes two or more silicon-oxygen bonds and a carbon-carbon double bond. In some cases, the silicon precursor includes one or more of:

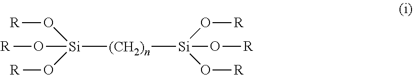

where n is 1 or 2 and each R is independently selected from a C1-C2 alky group;

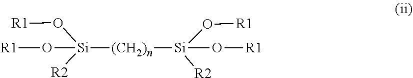

where n is 1 or 2 and each R1 and R2 is independently selected from a C1-C2 alky group or an alkene functional group;

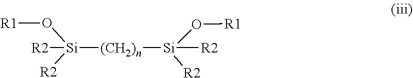

where n is 1 or 2 and each R1 and R2 is independently selected from a C1-C2 alky group or an alkene functional group; or

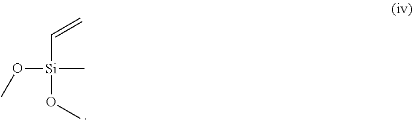

In some cases, a chemical formula of the silicon precursor consists of Si, C, H, and O.

In accordance with further embodiments of the disclosure, a method of forming a photoresist adhesion layer includes providing a silicon precursor to the reaction chamber, providing oxygen-free gas into the reaction chamber, and forming activated species that react with the silicon precursor or a derivative thereof to form the adhesion layer, wherein the step of forming activated species is performed at a temperature greater than 75° C., 85° C., or 100° C., or at a temperature of at least 100° C. and no more than 180° C. or at a temperature of at least 180° C. and no more than 300° C. The silicon precursor can be as noted above.

In accordance with additional exemplary embodiments of the disclosure, a structure that includes an underlayer and an adhesion layer is provided.

In accordance with further examples of the disclosure, a system for performing a method as described herein is provided. Exemplary systems include a reaction chamber, a silicon precursor source fluidly coupled to the reaction chamber, an inert gas source fluidly coupled to the reaction chamber, and a controller configured to perform a method as described herein or a portion thereof. The silicon precursor source can include a vessel and a silicon precursor as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates another method in accordance with exemplary embodiments of the disclosure.

FIG. 3 illustrates another method in accordance with exemplary embodiments of the disclosure.

FIG. 4 illustrates a timing sequence in accordance with examples of the disclosure.

FIG. 5 illustrates a structure in accordance with exemplary embodiments of the disclosure.

FIG. 6 illustrates a system configured for executing a method as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to methods of forming structures that include a photoresist underlayer (or bulk layer) and an adhesion layer overlying the underlayer or bulk layer, to structures including a photoresist underlayer and an adhesion layer, and to systems for forming such structures. As described in more detail below, exemplary methods can be used to form photoresist underlayer structures with photoresist underlayers and adhesion layers that provide desired properties, such as desired thickness (e.g., less than 10 or less than 5 nm), relatively low surface roughness, good adhesion to the photoresist, desired etch selectivity, desired thickness uniformity—both within a substrate (e.g., a wafer) and between substrates, high pattern quality (low number of defects and high pattern fidelity), low line width roughness (LWR), photoresist stability during EUV lithography processing—e.g., during any post-exposure bake (PEB), photoresist development, reworking of the substrate, and compatibility with integration. Further, as set forth in more detail below, methods, and particularly steps of forming the adhesion layer, can be performed at relatively high temperatures, relative to other adhesion layer formation temperatures, which allows for relative high throughput.

As used herein, the term “substrate” may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate.

In some embodiments, “film” refers to a layer extending in a direction perpendicular to a thickness direction. In some embodiments, “layer” refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a noble gas.

In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than precursors, that activates a precursor, modifies a precursor, or catalyzes a reaction of a precursor; a reactant may provide an element (such as O, N or C) to a film matrix and become a part of the film matrix. In some cases, the terms precursor and reactant can be used interchangeably. The term “inert gas” refers to a gas that does not take part in a chemical reaction to an appreciable extent and/or a gas that excites a precursor when, for example, RF or microwave power is applied to form a plasma, but unlike a reactant, an inert gas may not become a part of a film matrix to an appreciable extent.

The term “cyclic deposition process” or “cyclical deposition process” may refer to processes in which one or more of a precursor flow to a reaction chamber, a reactant flow to a reaction chamber, or plasma power is pulsed. Cyclical deposition processes include, for example, processing techniques, such as atomic layer deposition (ALD), cyclical chemical vapor deposition (cyclical CVD), and hybrid cyclical deposition processes that include an ALD component and a cyclical CVD component.

The term “atomic layer deposition” may refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, when performed with pulses of precursor(s) and/or reactants and/or plasma power.

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas or an inert gas) may subsequently be introduced into the process chamber for use in converting the chemisorbed precursor to the desired material on the deposition surface. The reactant/inert gas can be capable of further reaction or interaction with the precursor. Purging steps can be utilized during one or more cycles to remove any excess precursor from the process chamber and/or remove any excess reactant and/or reaction byproducts from the reaction chamber.

In this disclosure, continuously can refer to one or more of without breaking a vacuum, without interruption as a timeline, without any material intervening step, without changing treatment conditions, immediately thereafter, as a next step, or without an intervening discrete physical or chemical structure or layer between two structures or layers in some embodiments. For example, a reactant and/or an inert or noble gas can be supplied continuously during two or more steps and/or cycles of a method.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In accordance with aspects of the disclosure, any defined meanings of terms do not necessarily exclude ordinary and customary meanings of the terms.

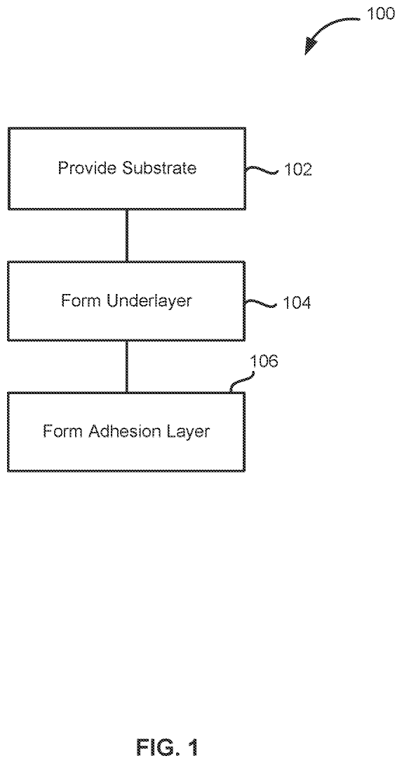

Turning now to the figures, FIG. 1 illustrates a method 100 of forming a structure comprising a photoresist underlayer in accordance with exemplary embodiments of the disclosure. Method 100 includes the steps of providing a substrate (step 102), forming an underlayer (step 104), and forming an adhesion layer (step 106).

Step 102 includes providing a substrate, such as a substrate described herein. The substrate can include one or more layers, including one or more material layers, to be subsequently etched. By way of examples, the substrate can include a deposited oxide, a native oxide, and/or an amorphous carbon layer to be etched. The substrate can include several layers underlying the material layer(s) to be etched.

During step 104, a bulk underlayer layer (often referred to herein as underlayer) is formed on a surface of the substrate using a first plasma process. The first plasma process may be a first cyclical deposition process. Use of a cyclical deposition process may be desirable, because such a process allows for the formation of an underlayer with desired thickness—e.g., less than 10 nm or less than or about equal to 5 nm or between about 2 nm and about 10 nm, with improved thickness uniformity—both within a substrate and from substrate-to-substrate.

In accordance with examples of the disclosure, a temperature within a reaction chamber during step 104 can be less than 500° C., less than 300° C., less than 100° C. or between about 50° C. and about 500° C., or between about 50° C. and about 300° C. or between about 50° C. and about 100° C. or greater than 75° C., 85° C., or 100° C., or at a temperature of at least 100° C. and no more than 180° C. or at a temperature of at least 180° C. and no more than 300° C. A pressure within the reaction chamber during step 104 can be between about 200 Pa and about 800 Pa or between about 100 Pa and about 2000 Pa.

In accordance with exemplary embodiments of the disclosure, step 104 includes forming or depositing one or more of a silicon or metal oxide, a silicon or metal nitride, and a silicon or metal oxynitride. Such oxides, nitrides, and/or oxynitrides can also include carbon.

The underlayer can include, for example, one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. The metal can include, for example, one or more metals selected from the group consisting of titanium, tantalum, tungsten, tin, and hafnium. In some cases, the underlayer includes carbon. The carbon can be incorporated into the underlayer as the underlayer is deposited and/or a carbon treatment can be applied to a surface of the underlayer. Additionally or alternatively, a carbon-containing layer or other layer can be deposited onto a surface of the underlayer.

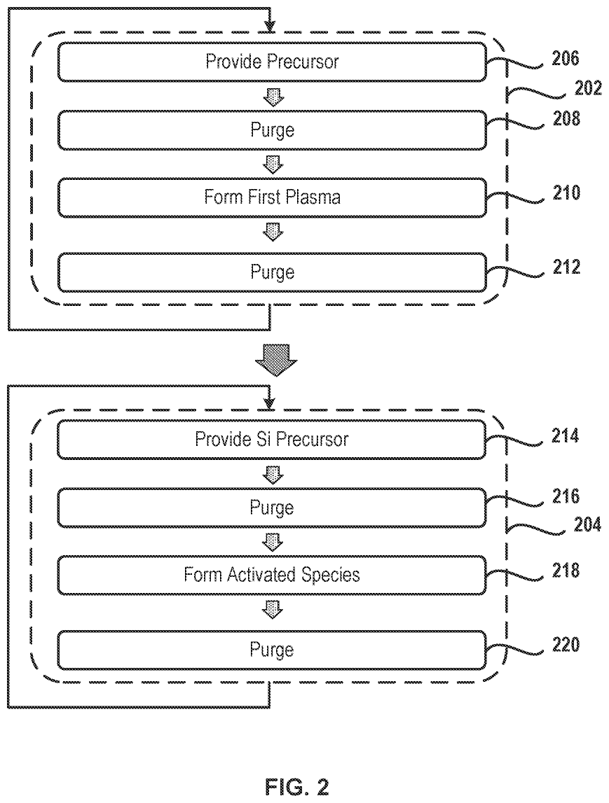

A first cyclical process 202 (e.g., a first (cyclical) plasma process) suitable for forming the underlayer in accordance with step 104 is illustrated in FIG. 2. First cyclical process 202 can include pulsing a (e.g., first) precursor comprising a metal or silicon into a reaction chamber (step 206) and forming a first plasma (step 210). First cyclical process 202 can also include purge steps 208 and 212. Cyclical process 202 can be repeated—e.g., between about 1 and about 10 or between about 100 and about 500 times before method 100 proceeds to step 106.

In some cases, the cyclical process for forming the underlayer can include (A) pulsing a first precursor comprising a metal into a reaction chamber, (B) pulsing a second precursor or reactant comprising an oxidant and/or nitriding agent into the reaction chamber, and (C) pulsing a carbon precursor into the reaction chamber. Each of the pulses can be separated by a purge step. Further, each pulsing step or a combination of pulsing steps (e.g., pulsing steps (A) and (B)) can be repeated a number of times prior to proceeding to the next step to tune a composition of the underlayer. For example, a range of ratios of (AB):C can be about 1:1 to about 1:10. Unless otherwise noted, steps (A) and (B) or steps (A), (B), and (C) can be performed in any order and various combinations of the steps can be repeated. In these cases, a plasma can be formed during one or more of steps (A), (B), and (C), such as (B) and/or (C).

In accordance with exemplary aspects of the disclosure, a precursor comprising silicon is provided during step 206. In some cases, the silicon precursor can also include carbon. Exemplary silicon precursors suitable for use in forming the underlayer include silicon precursors noted below in connection with process 204.

In accordance with other exemplary aspects of the disclosure, a precursor provided during step 206 comprises a metal. In these cases, the precursor can include a transition metal, such as one or more metals selected from the group consisting of titanium, tantalum, tungsten, tin, and hafnium. The precursor comprising a metal can also include carbon—e.g., one or more organic groups bonded directly or indirectly to a metal atom. By way of particular examples, the precursor comprising a metal can include a metal halide or a metal organic compound, or an organometallic compound, such as one or more of tetrakis(dimethylamino)titanium (TDMAT), titanium isopropoxide (TTIP), titanium chloride (TiCl), tetrakis(ethylmethylamino)hafnium (TEMAHf), hafnium chloride (HfCl), trimethylaluminum (TMA), triethylaluminium (TEA), other metal halide, or other metal-containing compounds.

When used, the carbon precursor can include any suitable organic compound, such as compounds comprising carbon and oxygen. In some cases, the carbon precursor can also include nitrogen. The carbon precursor can be selected to react with, for example, an —OH terminated surface of metal oxides and/or a —NH₂ terminated surface of a metal nitride. Examples of suitable carbon precursors include one or more of organic compounds, such as acid anhydrate (e.g., an acetic anhydrate), toluene, diethylene glycol, triethylene glycol, acetaldehyde, and organosilicon compounds, such as silanes, and siloxanes. Exemplary organosilicon compounds include (n,n-dimethylamino)trimethylsilane, trimethoxy(octadecyl)silane, hexamethyldisilazane, trimethoxy(3,3,3-trifluoropropyl)silane, trimethoxyphenylsilane, trichloro(3,3,3-trifluoropropyl)silane and hexamethyldisilazane.

The precursor flowrate including carrier gas can be between about 10 and about 6000 sccm. A precursor feed or pulse time during step 206 can be greater than 0.01 seconds or greater than 0.15 seconds or between about 0.1 and about 2 seconds or between about 0.01 and about 4 seconds.

During step 210, one or more of a reactant or an inert gas can be provided to the reaction chamber to form a plasma. A reactant provided during step 210 can include an oxidizing reactant, a nitriding reactant, a reducing agent, such as a hydrogen-containing reactant, and/or an inert gas. The oxidizing and/or nitriding reactant include reactants that include one or more of oxygen and nitrogen. In some cases, the reactant can include both nitrogen and oxygen. And, in some cases, the two or more oxidizing and/or nitriding reactants can be provided to the reaction chamber in an overlapping manner. Particular examples of reactants and inert gases that can be used to form a plasma during step 210 include Ar, He, N₂, O₂, CO, CO₂, N₂O, H₂, and the like, and any combination thereof.

In some cases, the reactant can be continuously flowed to the reaction chamber during one or more deposition cycles of process 202. A reactant flowrate during step 210 can be between about 5 and about 100 sccm or between about 0.1 and about 6 slm.

During step 210, the reactant and/or inert gas can be exposed to a (e.g., direct) plasma to form excited species for use in, e.g., a PEALD process using the first plasma process.

In accordance with examples of the disclosure, a plasma power for the first plasma process can be less than 150 W or between about 10 and about 150 W or between about 10 and about 400 W or between about 10 and 1000 W. A plasma on time during step 210 can be less than 4 seconds or less than 2 seconds or between about 0.1 and about 4 seconds. A gap between a plasma electrode and a substrate can be between about 7 mm and about 15 mm or between about 6 mm and about 18 mm.

During purge steps 208 and 212, any excess precursor and/or any reaction byproducts can be purged from the reaction chamber. The purge can be performed by, for example, supplying an inert gas and/or reactant to the reaction chamber and/or using a vacuum source. A purge time during step 208 or step 212 can be, for example, between about 0.2 and about 0.6 seconds or between about 0.15 and about 1 second or between about 0.1 and about 4 seconds.

Once the underlayer layer is formed, an adhesion layer is formed during step 106 using a second plasma process (e.g., a second cyclical plasma deposition process). Step 106 can be performed in situ—within the same reaction chamber and without an air and/or a vacuum break.

Step 106 can be performed using process 204, illustrated in FIG. 2. Step 106/process 204 can be or include a cyclical deposition process, such as a second cyclical plasma deposition process (e.g., a PEALD process). For example, process 204 can include providing (e.g., pulsing) a silicon precursor to the reaction chamber (step 214) and forming activated species (step 218). Step 218 can include, for example, providing oxygen-free gas into the reaction chamber and forming a plasma using the oxygen-free gas to form activated species that react with the silicon precursor or a derivative thereof to form the adhesion layer. Process 204 can additionally include purge steps 216, 220, which can be the same or similar to purge steps 208, 212, accounting for any differences in reactants that may be used in the respective processes 202, 204. Process 204 (i.e., steps 214-220) can be repeated a number of times—e.g., about 10 to about 50 or about 150 to about 200 or about 300 to about 400 or about 100 to about 500 times. A thickness of the adhesion layer can be greater than 0 nm and less than 2 nm.

The temperature and pressure during step 106/process 204 can be the same or similar or different for step 102 and/or 104. In accordance with examples of the disclosure, process 204 is performed at a temperature greater than 75° C., 85° C., or 100° C., or at a temperature of at least 100° C. and no more than 180° C. or at a temperature of at least 180° C. and no more than 300° C.

During step 214, a silicon precursor is provided to the reaction chamber. In accordance with examples of the disclosure, the silicon precursor does not comprise nitrogen. N-free precursors can be beneficial for use in forming an adhesion layer, because nitrogen is thought to exhibit a poisoning effect due to the presence of N atoms.

In accordance with examples of the disclosure, the silicon precursor can include one or more of:
(i) a molecule comprising a backbone comprising:

Si—(CH2)n—Si,
where n is between about 1 to about 10; or
(ii) a molecule comprising a carbon-carbon double bond.

In accordance with further examples, the molecule comprises two or more silicon-oxygen bonds. In some cases, the molecule comprises four or more silicon-oxygen bonds. Additionally or alternatively, the molecule can include two or more silicon-oxygen bonds and a carbon-carbon double bond.

In accordance with further examples, the silicon precursor consists of or consists essentially of Si, C, H, and O, which may be provided to the reaction chamber with the aid of a carrier gas. By way of examples, the silicon precursor comprises one or more of:

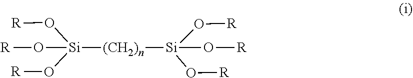

where n is 1 or 2 and each R is independently selected from a C1-C2 alky group;

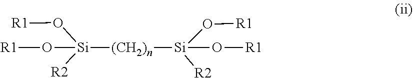

where n is 1 or 2 and each R1 and R2 is independently selected from a C1-C2 alky group or an alkene functional group;

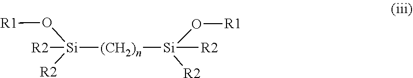

where n is 1 or 2 and each R1 and R2 is independently selected from a C1-C2 alky group or an alkene functional group; or

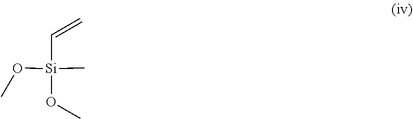

By way of examples, the silicon precursor can be selected from one or more of the group consisting of: 1,2-bis(triethoxysily)ethane, 1,2-bis(methyldiethixysily)ethane, bis(ethoxydimethylsilyl)methane, and dimethoxymethylvinylsilane. In some cases, the silicon precursor provided in step 216 can be on include the same silicon precursor provided during step 206.

A flowrate of the silicon precursor and any carrier gas during step 214 can be between about 10 sccm and about 6000 sccm. A duration of step 214 can be between about 0.1 s and about 4 s. During step 216, excess silicon precursor and/or any reaction byproducts can be purged from the reaction chamber after step 214.

During step 218, an oxygen-free gas is provided into the reaction chamber. The oxygen-free gas can be or include one or more of Ar, He, Ne, Kr, H₂ and Xe. A flowrate of the oxygen-free gas can be between about 3 slm and about 6 slm or about 2 slm and about 8 slm or about 1 slm and about 12 slm. In some cases, the oxygen-free gas can be continuously provided during one or more of steps 214-220.

Also during step 218, a plasma is formed using the oxygen-free gas. A power to form the plasma can be between about 30 W and about 400 W or between about 10 W and about 1000 W. A frequency of the power to form the plasma can be between about 200 kHz and about 2.45 GHz. A duration of a step of supplying power to form the plasma can be between about 0.1 s and about 4 s.

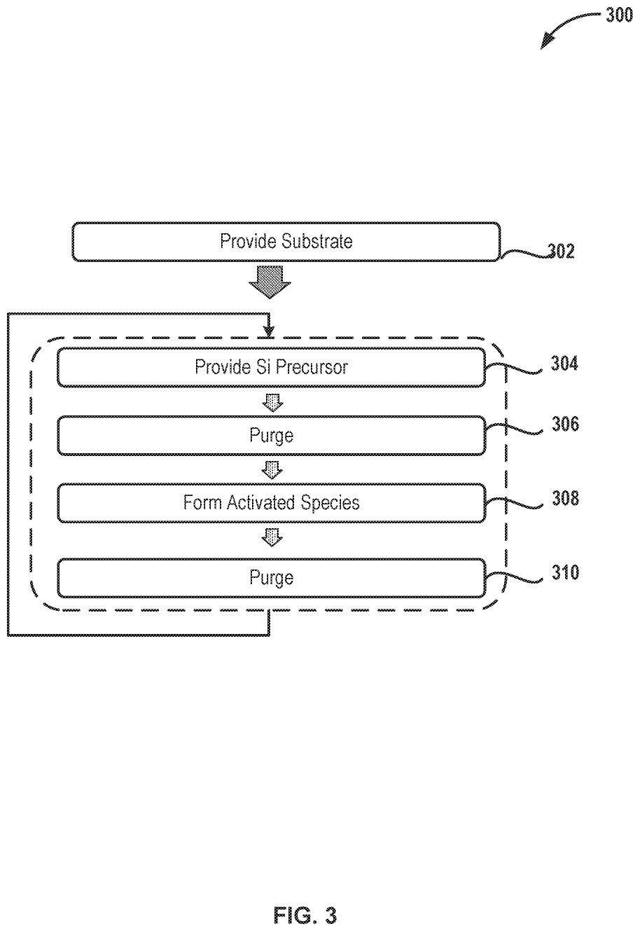

FIG. 3 illustrates a method of forming a photoresist adhesion layer 300 in accordance with further examples of the disclosure. Method 300 can be similar to or the same as process 204, except method 300 need not necessarily follow process 202. Method 300 includes the steps of providing a substrate within a reaction chamber (step 302), providing a silicon precursor to the reaction chamber (step 304), and forming activated species that react with the silicon precursor or a derivative thereof to form the adhesion layer (step 308). Method 300 can also include purge steps 306 and 310.

Step 302 can be the same or similar to step 102 described above. Steps 304-310 can be the same as or similar to steps 214-220. For example, step 308 can include providing oxygen-free gas into the reaction chamber and forming a plasma.

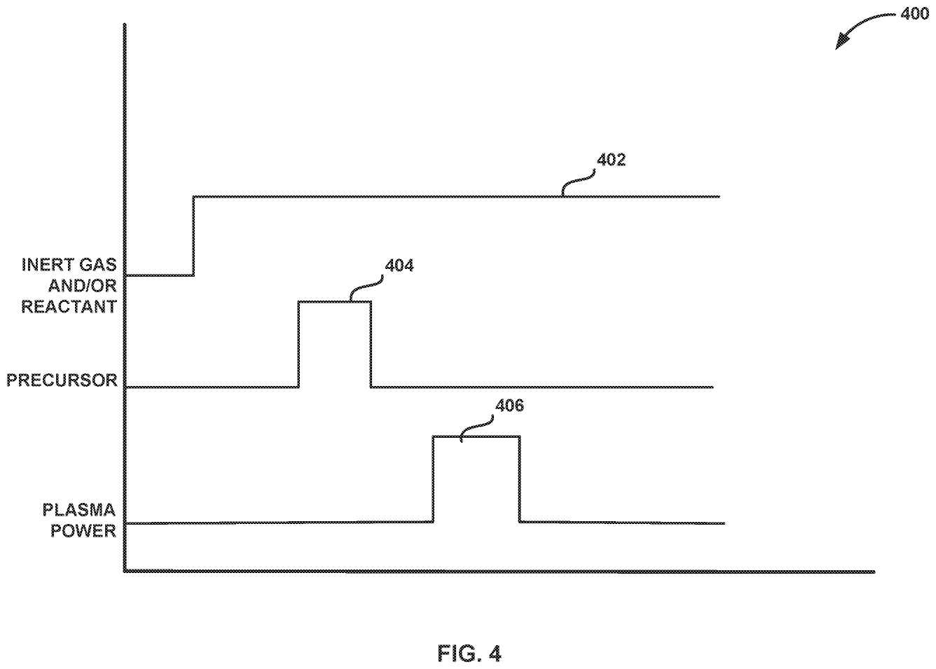

FIG. 4 illustrates a timing sequence 400 of a deposition cycle suitable for use with process 202 and/or 204 and/or method 300. As illustrated, a reactant and/or inert gas can be provided to the reaction chamber continuously (line 402) through one or more precursor pulses 404 and/or one or more plasma power pulses 406. Exemplary precursor and power pulses are described above in connection with steps 206, 210, 214, and 218. The deposition cycle can be repeated as noted above.

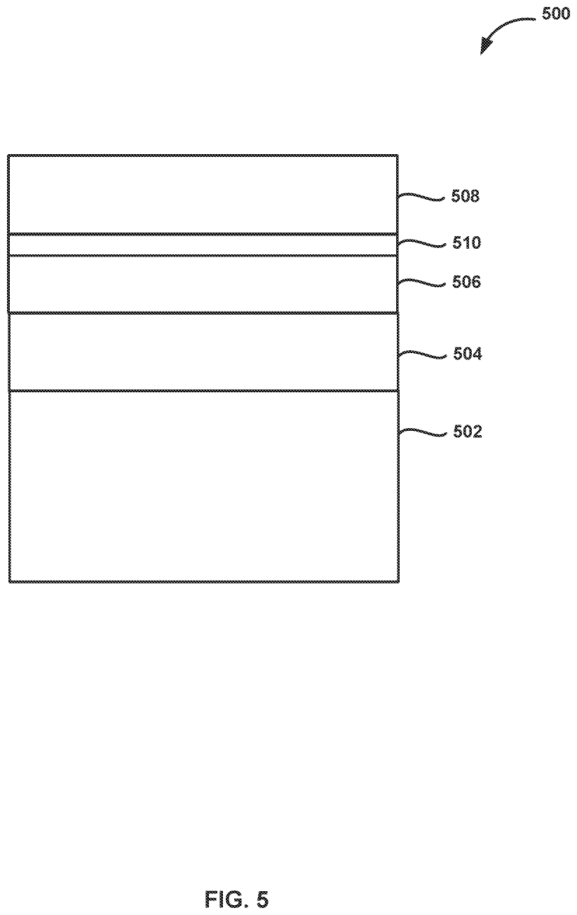

FIG. 5 illustrates a structure 500 in accordance with exemplary embodiments of the disclosure. Structure 500 can be formed using, for example, method 100 and/or timing sequence 400.

As illustrated, structure 500 includes a substrate 502, a material layer 504, a photoresist underlayer 506, an adhesion layer 510, and a photoresist layer 508. Adhesion layer 510 is between and in contact with underlayer 506 and photoresist layer 508.

Substrate 502 can include a substrate as described above. By way of examples, substrate 502 can include a semiconductor substrate, such as a bulk material, such as silicon (e.g., single-crystal silicon), other Group IV semiconductor material, Group III-V semiconductor material, and/or Group II-VI semiconductor material and can include one or more layers (e.g., a patterning stack) overlying the bulk material. Further, as noted above, substrate 502 can include various topologies, such as recesses, lines, and the like formed within or on at least a portion of a layer of the substrate.

Material layer 504 can be patterned and etched using a photoresist underlayer, adhesion layer, and a layer of photoresist as described herein. Exemplary materials suitable for material layer 504 include, for example, oxides, such as native oxides or field oxides. Other exemplary material layer 504 materials include amorphous carbon, nitrides, other oxides, silicon, and add-on films (e.g., a self-assembled monolayer (e.g., hexamethyldisilazane (HMDS)).

Underlayer 506 can include a bulk underlayer formed in accordance with a method described herein (e.g., method 100) and/or have properties and/or material as described herein. Exemplary underlayers include one or more of a silicon or metal oxide, a silicon or metal nitride, and a silicon or metal oxynitride—any of which can include or not include carbon. For example, underlayer 506 can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

A thickness of underlayer 506 can depend on a composition of material layer 504, a thickness of material layer 504, a type of photoresist, and the like. In accordance with examples of the disclosure, underlayer 506 has a thickness of less than 10 nm or less than or about 5 nm or between about 3 nm and about 10 nm or between 2 nm and 10 nm. If underlayer 506 is too thick, residual underlayer material may remain after an etch step. If underlayer 506 is too thin, underlayer 506 may not provide desired pattern transfer during an etch process.

Adhesion layer 510 desirably exhibits good adhesion and other properties as described herein. In accordance with examples of the disclosure, adhesion layer 510 includes silicon and can optionally include one or more of carbon, hydrogen, and oxygen. As noted above, adhesion layer 510 may desirably not include nitrogen.

To provide desired adhesion between photoresist layer 508 and underlayer 506, adhesion layer 510 may have or be tuned to have desired surface chemistry properties, e.g., quantified as surface energy, which is further categorized into a polar part of surface energy and a disperse part of surface energy.

By way of examples, with the utilization of an oxygen-free gas to form adhesion layer 510, dangling bonds potentially behave as the surface reactive sites and lead to the chemisorption when the silicon precursor is introduced onto the film. Hence, ligands (e.g., CHx ligands) in the silicon precursor structure can eventually remain on the surface, which results in a desired surface free energy. Adhesion layer 510 can be intrinsically SiOC, ending up with surface hydrocarbons.

Photoresist layer 508 can be or include positive or negative tone (e.g., EUV) photoresist.

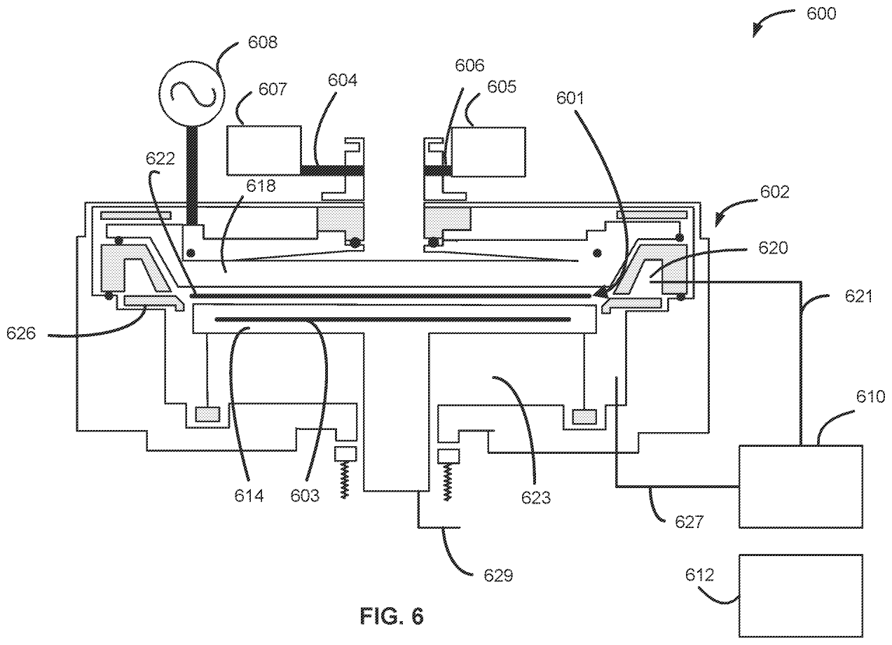

Turning now to FIG. 6, a reactor system 600 in accordance with exemplary embodiments of the disclosure is illustrated. Reactor system 600 can be used to perform one or more steps or substeps as described herein and/or to form one or more structures or portions thereof as described herein.

Reactor system 600 includes a pair of electrically conductive flat-plate electrodes 614, 618 typically in parallel and facing each other in an interior 601 (reaction zone) of a reaction chamber 602. Although illustrated with one reaction chamber 602, reactor system 600 can include two or more reaction chambers. A plasma can be excited within interior 601 by applying, for example, RF power from plasma power source(s) 608 to one electrode (e.g., electrode 618) and electrically grounding the other electrode (e.g., electrode 614). A temperature regulator 603 (e.g., to provide heat and/or cooling) can be provided in a lower stage 614 (the lower electrode), and a temperature of a substrate 622 placed thereon can be kept at a desired temperature, such as the temperatures noted above. Electrode 618 can serve as a gas distribution device, such as a shower plate or showerhead. Precursor gases, reactant gases, and a carrier or inert gas, if any, or the like can be introduced into reaction chamber 602 using one or more gas lines (e.g., reactant gas line 604 and precursor gas line 606, respectively, coupled to a reactant source 607 and a precursor (e.g., silicon) source 605). For example, an inert gas and a reactant (e.g., as described above) can be introduced into reaction chamber 602 using line 604 and/or a precursor and a carrier gas (e.g., as described above) can be introduced into the reaction chamber using line 606. Although illustrated with two inlet gas lines 604, 606, reactor system 600 can include any suitable number of gas lines.

In reaction chamber 602, a circular duct 620 with an exhaust line 621 can be provided, through which gas in the interior 601 of the reaction chamber 602 can be exhausted to an exhaust source 610. Additionally, a transfer chamber 623 can be provided with a seal gas line 629 to introduce seal gas into the interior 601 of reaction chamber 602 via the interior (transfer zone) of transfer chamber 623, wherein a separation plate 626 for separating the reaction zone and the transfer chamber 623 can be provided (a gate valve through which a substrate is transferred into or from transfer chamber 623 is omitted from this figure). Transfer chamber 623 can also be provided with an exhaust line 627 coupled to an exhaust source 610. In some embodiments, continuous flow of a carrier gas to reaction chamber 602 can be accomplished using a flow-pass system (FPS).

Reactor system 600 can include one or more controller(s) 612 programmed or otherwise configured to cause one or more method steps as described herein to be conducted. Controller(s) 612 are coupled with the various power sources, heating systems, pumps, robotics and gas flow controllers, or valves of the reactor, as will be appreciated by the skilled artisan. By way of example, controller 612 can be configured to control gas flow of a precursor, a reactant, and/or an inert gas into at least one of the one or more reaction chambers to form a layer as described herein. Controller 612 can be further configured to provide power to form a plasma—e.g., within reaction chamber 602. Controller 612 can be similarly configured to perform additional steps as described herein.

Controller 612 can include electronic circuitry and software to selectively operate valves, manifolds, heaters, pumps and other components included in system 600. Such circuitry and components operate to introduce precursors, reactants, and purge gases from the respective sources. Controller 612 can control timing of gas pulse sequences, temperature of the substrate and/or reaction chamber, pressure within the reaction chamber, plasma power, and various other operations to provide proper operation of the system 600, such as in the performance of timing sequence 100.

Controller 612 can include control software to electrically or pneumatically control valves to control flow of precursors, reactants, and/or purge gases into and out of the reaction chamber 602. Controller 612 can include modules, such as a software or hardware component, e.g., a FPGA or ASIC, which performs certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 600, substrates, such as semiconductor wafers, are transferred from, e.g., a substrate handling area 623 to interior 601. Once substrate(s) are transferred to interior 601, one or more gases, such as precursors, reactants, carrier gases, and/or purge gases, are introduced into reaction chamber 602.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming a structure comprising a photoresist underlayer, the method comprising the steps of:
providing a substrate within a reaction chamber;
forming a photoresist underlayer overlying a surface of the substrate using a first plasma process; and
forming an adhesion layer using a second plasma process comprising:
providing a silicon precursor to the reaction chamber;
providing oxygen-free gas into the reaction chamber; and
forming activated species that react with the silicon precursor or a derivative thereof to form the adhesion layer,
wherein the second plasma process is performed at a temperature greater than 75° C., 85° C., or 100° C., or at a temperature of at least 100° C. and no more than 180° C. or at a temperature of at least 180° C. and no more than 300° C.

2. The method of claim 1, wherein the photoresist underlayer comprises one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

3. The method of claim 1, wherein the step of forming a photoresist underlayer comprises forming a metal oxide.

4. The method of claim 3, wherein the metal oxide comprises one or more of titanium, tantalum, tungsten, tin, and hafnium.

5. The method of claim 1, wherein the step of forming a photoresist underlayer comprises forming a silicon oxide.

6. The method of claim 1, wherein the silicon precursor comprises one or more of:
(i) a molecule comprising a backbone comprising:
Si—(CH₂)ₙ—Si,
where n is between about 1 and about 10; or
(ii) a molecule comprising a carbon-carbon double bond.

7. The method of claim 6, wherein the molecule comprises two or more silicon-oxygen bonds.

8. The method of claim 6, wherein the molecule comprises four or more silicon-oxygen bonds.

9. The method of claim 6, wherein the molecule comprises two or more silicon-oxygen bonds and a carbon-carbon double bond.

10. The method of claim 1, wherein the silicon precursor does not comprise nitrogen.

11. The method of any of claim 1, wherein the silicon precursor comprises one or more of: 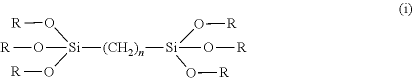
where n is 1 or 2 and each R is independently selected from a C1-C2 alky group; 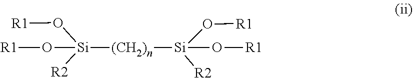
where n is 1 or 2 and each R1 and R2 is independently selected from a C1-C2 alky group or an alkene functional group; 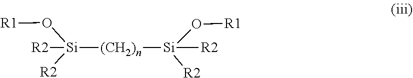
where n is 1 or 2 and each R1 and R2 is independently selected from a C1-C2 alky group or an alkene functional group; or

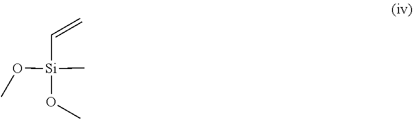

12. The method of claim 1, wherein a chemical formula of the silicon precursor consists of Si, C, H, and O.

13. The method of claim 1, wherein the silicon precursor comprises one or more of 1,2-bis(triethoxysily)ethane; 1,2-bis(methyldiethixysily)ethane; bis(ethoxydimethylsilyl)methane, and dimethoxymethylvinylsilane.

14. The method of claim 1, wherein the photoresist underlayer is formed using the silicon precursor.

15. The method of claim 1, wherein the first plasma process comprises a first cyclical plasma deposition process.

16. The method of claim 1, wherein the second plasma process comprises a second cyclical plasma deposition process.

17. The method of claim 15, wherein the first cyclic deposition process is repeated between about 1 and about 10 or about 100 and about 500 times.

18. The method of claim 15, wherein the second cyclic deposition process is repeated between about 10 and about 50 or about 100 and about 500 times.

19. A method of forming a photoresist adhesion layer, the method comprising the steps of:
providing a silicon precursor to the reaction chamber;
providing oxygen-free gas into the reaction chamber; and
forming activated species that react with the silicon precursor or a derivative thereof to form the adhesion layer,
wherein the step of forming activated species is performed at a temperature greater than 75° C., 85° C., or 100° C., or at a temperature of at least 100° C. and no more than 180° C. or at a temperature of at least 180° C. and no more than 300° C.

20. The method of claim 19, wherein the method comprises a plasma-enhanced cyclical deposition process.

21. The method of claim 19, wherein the silicon precursor comprises one or more of: 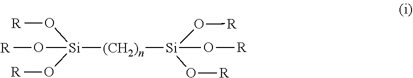
where n is 1 or 2 and each R is independently selected from a C1-C2 alky group; 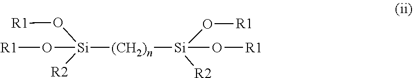
where n is 1 or 2 and each R1 and R2 is independently selected from a C1-C2 alky group or an alkene functional group, or 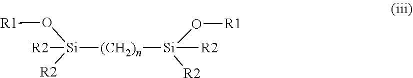
where n is 1 or 2 and each R1 and R2 is independently selected from a C1-C2 alky group or an alkene functional group,

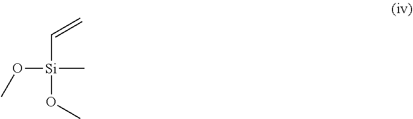

22. A structure formed according to the method of claim 1.

23. The structure of claim 22, further comprising an EUV photoresist overlying and in contact with the adhesion layer.

24. A reactor system for forming an adhesion layer, the system comprising:
a reaction chamber;
a silicon precursor source fluidly coupled to the reaction chamber;
an inert gas source fluidly coupled to the reaction chamber; and
a controller configured to perform the method according to claim 1.
